(19) United States
(12) Patent Application Publication
(10) Pub. No.: US 2025/0246139 A1
(43) Pub. Date: Jul. 31, 2025

(54) DISPLAY APPARATUS

(71) Applicant: LG DISPLAY CO., LTD., Seoul (KR)

(72) Inventors: Ji Eun KANG, Paju-si (KR); Jong Seok KIM, Paju-si (KR)

(73) Assignee: LG DISPLAY CO., LTD., Seoul (KR)

(21) Appl. No.: 18/817,918

(22) Filed: Aug. 28, 2024

(30) Foreign Application Priority Data
Jan. 26, 2024 (KR) 10-2024-0012479

(51) Int. Cl. G09G 3/3233

(52) U.S. Cl. CPC G09G 3/3233; G09G 2300/0452; G09G 2300/0842; G09G 2330/023

(57) ABSTRACT

Disclosed is a display device that is driven in a variable refresh rate (VRR) manner and is capable of preventing occurrence of defects in a display panel caused by occurrence of a ripple in an anode reset voltage VAR. In one aspect, a display device includes a substrate on which a plurality of pixels is disposed in a column direction and a row direction; a first anode reset line disposed in each row in which a first subset of pixels among the plurality of pixels are located; and a second anode reset line disposed in each row in which a second subset of pixels among the plurality of pixels are located.

### CROSS-REFERENCE TO RELATED APPLICATION

This application claims the benefit of Korean Patent Application No. 10-2024-0012479, filed on Jan. 26, 2024, which is hereby incorporated by reference as if fully set forth herein.

### BACKGROUND

### Field of the Disclosure

The present disclosure relates to a display device.

### Background

Display devices that display various types of information on a screen are being developed to be thinner, lighter, and more portable, and to have higher performance. Therefore, efforts are being made continuously to develop lightweight and thinner display devices.

Examples of display devices include a liquid crystal display (LCD) device, a quantum dot display (QDD) device, a field emission display (FED) device, and an organic light-emitting display (OLED) device.

Among these display devices, an OLED device is a self-emissive display device, and thus does not need a separate light source unlike an LCD device. Therefore, the OLED device has advantages of a light weight and a thin profile. In addition, the OLED device is advantageous in terms of power consumption due to the low-voltage driving property thereof, and has excellent color implementation performance, a high response speed, a wide viewing angle, and a high contrast ratio (CR). Thus, the OLED device is currently being developed as a next-generation display device.

### SUMMARY

Accordingly, the present disclosure is directed to a display device that substantially obviates one or more problems due to limitations and disadvantages of the related art.

Example objective of the present disclosure are directed to a display device that is driven in a variable refresh rate (VRR) manner and is capable of preventing occurrence of defects in a display panel caused by occurrence of a ripple in an anode reset voltage VAR.

The present disclosure is not limited to the above-mentioned object, and other objects not mentioned herein will be clearly understood by those skilled in the art from the following description.

Additional advantages, objects, and features of the disclosure will be set forth in part in the description which follows and in part will become apparent to those having ordinary skill in the art upon examination of the following or may be learned from practice of the disclosure. The objects and other advantages of the disclosure may be realized and attained by the structure pointed out in the written description and claims hereof as well as the appended drawings.

To achieve these objects and other advantages and in accordance with the purpose of the disclosure, as embodied and broadly described herein, a display device includes a substrate on which a plurality of pixels is disposed in a column direction and a row direction, a light-emitting diode disposed in each of the plurality of pixels, a first anode reset line disposed in each row in which some pixels among the plurality of pixels are located, and a second anode reset line disposed in the each row in which the remaining pixels among the plurality of pixels are located.

In one aspect, a display device includes a substrate on which a plurality of pixels is disposed in a column direction and a row direction; a first anode reset line disposed in each row in which a first subset of pixels among the plurality of pixels are located; and a second anode reset line disposed in each row in which a second subset of pixels among the plurality of pixels are located.

In another aspect, the plurality of pixels includes a first pixel connected to the first anode reset line; a second pixel connected to the first anode reset line; and a third pixel connected to the second anode reset line.

In another aspect, the first pixel disposed in a corresponding pixel row and the second pixel disposed in a next pixel row are connected to the first anode reset line, and wherein the third pixel disposed in the corresponding pixel row and the third pixel disposed in the next pixel row are connected to the second anode reset line.

In another aspect, the first anode reset line and the second anode reset line are disposed in each pixel row.

In another aspect, the first anode reset line and another first anode reset line adjacent thereto are connected to each other to have a mesh structure, and wherein the second anode reset line and another second anode reset line adjacent thereto are connected to each other to have a mesh structure.

In another aspect, the first pixel and the second pixel disposed in a corresponding pixel row are connected to the first anode reset line, and wherein the third pixel disposed in the corresponding pixel row is connected to the second anode reset line.

In another aspect, each of the plurality of pixels comprises one or more transistors, a driving transistor, and a storage capacitor.

In another aspect, a semiconductor layer of each of the driving transistor and the one or more transistors is an oxide semiconductor layer or a low-temperature polysilicon semiconductor layer.

In another aspect, the driving transistor is connected to a second node, and wherein the one or more transistors include a first transistor connected between the second node and a third node; a second transistor connected to a first node; a third transistor connected to the first node; a fourth transistor connected between the third node and a fourth node; a fifth transistor connected to the second node; a sixth transistor connected to the fourth node; and a seventh transistor connected to the first node.

In another aspect, the display device further includes a storage capacitor connected between a high-potential driving voltage terminal and the second node.

In another aspect, a light-emitting diode is connected between the fourth node and a low-potential driving voltage terminal.

In another aspect, the first anode reset line is disposed in a 2k^{th} pixel row (k being a natural number), and the second anode reset line is disposed in a (2k−1)^{th} pixel row.

In another aspect, a first pixel, a second pixel, the first pixel, a third pixel, the first pixel, and the second pixel are disposed in that order in the (2k−1)^{th} pixel row, and the first pixel, the third pixel, the first pixel, the second pixel, the first pixel, and the third pixel are disposed in that order in the 2k^{th} pixel row.

In another aspect, the third pixel and the second pixel disposed in a vertical direction in two adjacent pixel rows are connected to the first anode reset line, and the first pixel and another first pixel disposed in the vertical direction in two adjacent pixel rows are connected to the second anode reset line.

In another aspect, each of the plurality of pixels comprises one or more transistors and a driving transistor, and the first anode reset line or the second anode reset line include the same material as source and drain electrodes of one of the one or more transistors and the driving transistor.

In one aspect, a display device includes a substrate; a plurality of pixels on the substrate; a first anode reset line; a second anode reset line, wherein each of the plurality of pixels is connected to one of the first anode reset line or the second anode reset line, wherein the first anode reset line and another first anode reset line adjacent thereto are connected to each other to form a mesh structure, and wherein the second anode reset line and another second anode reset line adjacent thereto are connected to each other to form the mesh structure.

In another aspect, a first pixel, a second pixel, the first pixel, a third pixel, the first pixel, and the second pixel are disposed in that order in a (2k−1)^{th} pixel row (k being a natural number), and the first pixel, the third pixel, the first pixel, the second pixel, the first pixel, and the third pixel are disposed in that order in a 2k^{th} pixel row.

In one aspect, a display device includes a substrate on which a plurality of pixels is disposed in a column direction and a row direction; a first anode reset line disposed in a 2k^{th} pixel row (k being a natural number); and a second anode reset line disposed in a (2k−1)^{th} pixel row, wherein a first pixel disposed in the (2k−1)^{th} pixel row and another first pixel disposed in the 2k^{th} pixel row are connected to the second anode reset line, and wherein a second pixel disposed in the 2k^{th} pixel row and another second pixel disposed in a (2k+1)^{th} pixel row are connected to the first anode reset line.

In another aspect, the first pixel, the second pixel, the first pixel, the third pixel, the first pixel, and the second pixel are disposed in that order in the (2k−1)^{th} pixel row, and the first pixel, the third pixel, the first pixel, the second pixel, the first pixel, and the third pixel are disposed in that order in the 2k^{th} pixel row.

In one aspect, a display device includes a substrate on which a plurality of pixels is disposed in a column direction and a row direction; light-emitting diodes disposed in the plurality of pixels; a first anode reset line disposed in each of odd-numbered pixel rows and connecting pixels of different colors among the light-emitting diodes; and a second anode reset line disposed in each of even-numbered pixel rows and connecting pixels of the same color among the light-emitting diodes.

In another aspect, each of the plurality of pixels comprises one or more transistors, a driving transistor, and a storage capacitor, and a semiconductor layer of each of the driving transistor and the one or more transistors is an oxide semiconductor layer or a low-temperature polysilicon semiconductor layer.

In one aspect, the display device further includes an encapsulation member disposed on the light-emitting diodes; and a touch unit disposed on the encapsulation member.

### BRIEF DESCRIPTION OF THE DRAWINGS

The accompanying drawings, which are included to provide a further understanding of the disclosure and are incorporated in and constitute a part of this application, illustrate aspect(s) of the disclosure and together with the description serve to explain the principle of the disclosure. In the drawings:

FIG. 1 is a block diagram showing a display device according to an aspect of the present disclosure;

FIG. 2 is a circuit diagram of a pixel included in the display device according to the aspect of the present disclosure;

FIG. 3 is a cross-sectional view showing the display device according to the aspect of the present disclosure;

FIG. 4 is a diagram for explaining an operation method of the display device according to an aspect the present disclosure;

FIG. 5 is a layout diagram showing anode reset lines of the display device according to an aspect of the present disclosure;

FIG. 6 is a layout diagram showing the circuit configuration and anode reset lines of each pixel in the display device according to the aspect of the present disclosure;

FIG. 7 is an exemplary cross-sectional view showing the connection relationship of the anode reset lines according to an aspect of the present disclosure;

FIG. 8 is a layout diagram showing anode reset lines of the display device according to another aspect of the present disclosure;

FIG. 9 is a layout diagram showing the circuit configuration and anode reset lines of each pixel in the display device according to the other aspect of the present disclosure;

FIG. 10 is an exemplary cross-sectional view showing the connection relationship of the anode reset lines according to an aspect of the present disclosure;

FIG. 11 is a layout diagram showing anode reset lines of the display device according to still another aspect of the present disclosure; and

FIG. 12 is a layout diagram showing the circuit configuration and anode reset lines of each pixel in the display device according to the still other aspect of the present disclosure.

### DETAILED DESCRIPTION

Hereinafter, exemplary embodiments of the present disclosure will be described with reference to the accompanying drawings. Wherever possible, the same reference numerals will be used throughout the drawings to refer to the same or like parts.

In describing the present disclosure, when it is determined that a detailed description of a well-known technology associated with the present disclosure may unnecessarily make the gist of the present disclosure unclear, it will be omitted. In addition, the names of constituent elements used in the following description are selected in consideration of ease of writing the specification, and may differ from the names of parts of actual products.

In the drawings for explaining the exemplary embodiments of the present disclosure, for example, the illustrated shape, size, ratio, angle, and number are given by way of example, and thus, are not limited to the disclosure. Throughout the present specification, the same reference numerals designate the same constituent elements.

In addition, in the following description of the present disclosure, a detailed description of known functions and configurations incorporated herein will be omitted when it may make the subject matter of the present disclosure rather unclear.

The terms “comprises”, “includes”, and/or “has”, used in this specification, do not preclude the presence or addition of other elements unless used along with the term “only”. The singular forms are intended to include the plural forms as well, unless the context clearly indicates otherwise.

In the interpretation of constituent elements included in various embodiments of the present disclosure, the constituent elements are interpreted as including an error range even if there is no explicit description thereof.

In the description of the various embodiments of the present disclosure, when describing positional relationships, for example, when the positional relationship between two parts is described using “on”, “above”, “below”, “next to”, or the like, one or more other parts may be located between the two parts unless the term “directly” or “closely” is used.

In the description of the various embodiments of the present disclosure, when describing temporal relationships, for example, when the temporal relationship between two actions is described using “after”, “subsequently”, “next”, “before”, or the like, the actions may not occur in succession unless the term “directly” or “just” is used therewith.

It may be understood that, although the terms “first”, “second”, etc. may be used herein to describe various elements, these elements are not to be limited by these terms. These terms are merely used to distinguish one element from another. Therefore, in the present specification, an element indicated by “first” may be the same as an element indicated by “second” without exceeding the technical scope of the present disclosure, unless otherwise mentioned.

The respective features of the various embodiments of the present disclosure may be partially or entirely coupled to or combined with each other, and various technical linkages and modes of operation thereof are possible. These various embodiments may be performed independently of each other or may be performed in association with each other.

Hereinafter, a display device according to an aspect of the present disclosure will be described with reference to the accompanying drawings.

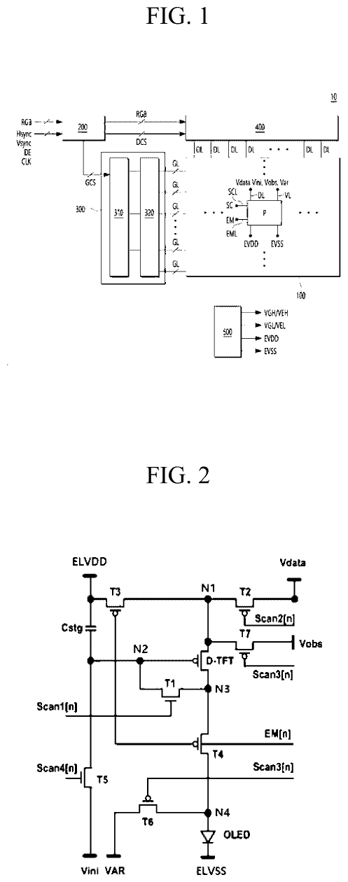

FIG. 1 is a block diagram showing a display device according to an aspect of the present disclosure.

As shown in FIG. 1, a display device according to an aspect of the present disclosure may include a display panel 100, a data driving circuit 400, a gate driving circuit 300, a power generation unit 500, and a timing controller 200.

A plurality of pixels P may be disposed on the display panel 100. The plurality of pixels P may be disposed in regions in which a plurality of data lines DL and a plurality of gate lines GL intersect each other. The pixels P disposed on the same horizontal line may constitute one pixel row. The pixels P disposed in one pixel row may be connected to one gate line GL, and one gate line GL may include at least one scan line and at least one emission line. For example, each pixel P may be connected to one data line DL, at least one scan line, and at least one emission line. However, the embodiments of the present disclosure are not limited thereto.

The data driving circuit 400 may drive the data lines DL. The gate driving circuit 300 may drive the gate lines GL. The power generation unit 500 may supply power required to drive each of the plurality of pixels P.

The plurality of pixels P may commonly receive a high-potential driving voltage ELVDD and a low-potential driving voltage ELVSS from the power generation unit 500. The plurality of pixels P may receive a bias voltage Vobs and an initialization voltage Vini from a power line VL, without being limited thereto.

Transistors or thin-film transistors (TFTs) constituting the pixel P may be implemented as an oxide TFT including an oxide semiconductor layer. The oxide TFT may be advantageous in terms of enlargement of the display panel 100, taking into consideration electron mobility and process deviation. However, the embodiments of the present disclosure are not limited thereto. The semiconductor layer of the TFT may be formed of amorphous silicon, polysilicon, or the like.

Each pixel P may include an organic light-emitting diode (OLED), a driving TFT configured to supply current to the organic light-emitting diode, a switching TFT configured to supply a data voltage to the driving TFT, and a storage capacitor configured to store the data voltage supplied to the driving TFT. The storage capacitor may maintain the data voltage during one frame.

Each pixel P may further include one or more TFTs and a storage capacitor to compensate for changes in threshold voltage of the driving TFT.

Touch sensors may be disposed on the display panel 100. Touch input may be sensed using the touch sensors or through the pixels P. The touch sensors may be implemented as on-cell type or add-on type touch sensors, which are disposed on a screen of the display panel, or may be implemented as in-cell type touch sensors, which are embedded in the display panel 100. However, the embodiments of the present disclosure are not limited thereto.

The timing controller 200 may control driving timing of the data driving circuit 400 and the gate driving circuit 300. The timing controller 200 may rearrange digital video data RGB, input from the outside, according to the resolution of the display panel 100 and may supply the rearranged digital video data to the data driving circuit 400.

Further, the timing controller 200 may generate a data control signal DDC for control of operation timing of the data driving circuit 400 and a gate control signal GDC for control of operation timing of the gate driving circuit 300 based on timing signals, such as a vertical sync signal Vsync, a horizontal sync signal Hsync, a dot clock signal DCLK, and a data enable signal DE.

The timing controller 200 may multiply an input frame frequency by “i” and may control operation timing of a display panel driver at a frame frequency of “input frame frequency^{×}i” Hz (where i is a positive integer greater than 0). The input frame frequency may be 60 Hz in a national television standards committee (NTSC) system and may be 50 Hz in a phase-alternating line (PAL) system. However, the embodiments of the present disclosure are not limited thereto.

The data driving circuit 400 may convert the digital video data RGB input from the timing controller 200 into an analog data voltage based on the data control signal DDC and may provide the analog data voltage to each of the data lines DL.

The data driving circuit 400 may include one or more source driver integrated circuits (ICs) SIC. The source driver ICs may convert digital video data of an input image into an analog gamma compensation voltage under the control of the timing controller 200 to generate a data voltage, and may output the data voltage to the data lines DL. The source driver ICs may be mounted on a bendable flexible circuit board, e.g., a chip-on-film (COF), or may be directly adhered to a substrate in a non-active area of the display panel 100 through a COG process.

The COFs may be adhered to a pad area of the display panel 100 and a source PCB through an anisotropic conductive film (ACF). Input pins of the COFs may be electrically connected to output terminals (pads) of the source PCB. Output pins of the COFs may be electrically connected to data pads formed on the substrate of the display panel 100 through the ACF.

Although one data driving circuit 400 is illustrated in FIG. 1 as being disposed on one side of the display panel 100, the number of data driving circuits 400 and the placement position thereof are not limited thereto. For example, the data driving circuit 400 may be composed of a plurality of integrated circuits (ICs), and the plurality of ICs may be separately disposed on one side of the display panel 100.

The gate driving circuit 300 may generate a scan signal and an emission signal based on the gate control signal GDC. The gate driving circuit 300 may include at least one scan driver 310 and an emission driver 320.

To drive at least one scan line SCL connected to each pixel row, the at least one scan driver 310 may generate a scan signal SC and may supply the same to the gate lines GL in a row-sequential manner. The at least one scan driver 310 may output a scan pulse in response to a start pulse and a shift clock from the timing controller 200 and may shift the scan pulse according to a shift clock timing.

To drive at least one emission line EML connected to each pixel row, the emission driver 320 may generate an emission signal EM and may supply the same to the emission lines in a row-sequential manner. The emission driver 320 may output an emission control signal pulse in response to a start pulse and a shift clock from the timing controller 200 and may sequentially shift the emission control signal pulse according to the shift clock.

The scan signal SC may include a scan pulse that swings between a gate-on voltage VGL and a gate-off voltage VGH. The emission control signal EM may include an emission control signal pulse that swings between a gate-on voltage VEL and a gate-off voltage VEH. The scan pulse may select pixels P of a line to which a data voltage Vdata is to be written. The emission control signal EM may define a light-emitting time of the pixels P.

The gate lines GL may supply a scan signal SC and an emission control signal EM to the plurality of pixels P, and the data lines DL may supply a data voltage Vdata to the plurality of pixels P. According to various embodiments, the gate lines GL may include a plurality of scan lines SCL for supply of the scan signal SC and a plurality of emission control signal lines EML for supply of the emission control signal EM.

The power supply unit 500 may generate direct-current (DC) power required to drive the pixel array of the display panel 100 and the display panel driver using a DC-DC converter. The DC-DC converter may include a charge pump, a regulator, a buck converter, or a boost converter. However, the embodiments of the present disclosure are not limited thereto.

The power supply unit 500 may receive a DC input voltage from a host system and may generate DC voltages, such as gate-on voltages VGL and VEL, gate-off voltages VGH and VEH, a high-potential driving voltage EVDD, and a low-potential driving voltage EVSS.

The gate-on voltages VGL and VEL and the gate-off voltages VGH and VEH may be supplied to a level shifter and the gate driving circuit 300. The high-potential driving voltage ELVDD and the low-potential driving voltage ELVSS may be commonly supplied to the pixels P.

The plurality of pixels P of the display panel 100 may include at least a first pixel, a second pixel, and a third pixel. The first pixel, the second pixel, and the third pixel may emit light of different colors. For example, the first pixel may be a red pixel, the second pixel may be a blue pixel, and the third pixel may be a green pixel. However, the embodiments of the present disclosure are not limited thereto.

The sizes of the plurality of pixels P may be identical to or different from each other. The sizes of the first pixel, the second pixel, and the third pixel may be designed to be different from each other in consideration of color balance or the lifespan of the organic light-emitting diode (OLED) included in each of the first pixel, the second pixel, and the third pixel.

To implement lower power consumption, the display device according to the present disclosure may employ variable refresh rate (VRR) technology that varies a driving frequency.

For example, the timing controller 200 may generate signals so that the pixels P may be driven at various refresh rates. For example, the timing controller 200 may generate driving-related signals so that the pixels P may be driven in a variable refresh rate (VRR) mode or to be switchable between a first refresh rate and a second refresh rate. For example, the timing controller 200 may simply change a speed of the clock signal, may generate a synchronization signal to generate a horizontal blank or a vertical blank, or may drive the gate driving circuit 300 in a mask manner, thereby driving the pixels P at various refresh rates.

Therefore, to vary the driving frequency, it is necessary to perform driving in an anode reset frame. To perform driving in the anode reset frame, each pixel may be configured to supply an anode reset voltage VAR.

FIG. 2 is a circuit diagram of a pixel included in the display device according to an aspect of the present disclosure.

As shown in FIG. 2, each pixel P may include a pixel driving circuit and an emission unit.

The pixel driving circuit may include first to seventh transistors T1 to T7, a storage capacitor Cstg, and a driving transistor D-TFT. The emission unit may include an organic light-emitting diode OLED.

The first to seventh transistors TI to T7 and the driving transistor D-TFT may be implemented as different types of transistors. For example, one transistor among the first to seventh transistors T1 to T7 and the driving transistor D-TFT may be a transistor using an oxide semiconductor as an active layer. Because an oxide semiconductor material has low off-current, the same may be suitable for a switching transistor that maintains a short turn-on time and a long turn-off time. In another example, another transistor among the first to seventh transistors T1 to T7 and the driving transistor D-TFT may be a transistor using low-temperature polysilicon (LTPS) as an active layer. Because a polysilicon material has high mobility and thus exhibits low power consumption and excellent reliability, the same may be suitable for a driving transistor D-TFT.

The first to seventh transistors T1 to T7 and the driving transistor D-TFT may be an N-type transistor or a P-type transistor. In an N-type transistor, because a carrier is an electron, an electron may flow from a source electrode to a drain electrode, and current may flow from the drain electrode to the source electrode. In a P-type transistor, because a carrier is a hole, a hole may flow from a source electrode to a drain electrode, and current may flow from the source electrode to the drain electrode. For example, one transistor among the first to seventh transistors T1 to T7 and the driving transistor D-TFT may be an N-type transistor, and another one transistor among the first to seventh transistors T1 to T7 and the driving transistor D-TFT may be a P-type transistor.

The pixel driving circuit may include the driving transistor D-TFT, the first to seventh transistors T1 to T7, and the storage capacitor Cstg.

The driving transistor D-TFT may include a first node N1, a second node N2, and a third node N3. In the driving transistor D-TFT, the second node N2 may be a gate node, the first node N1 may be a source node or a drain node, and the third node N3 may be a drain node or a source node. Hereinafter, for convenience of description, the driving transistor D-TFT, in which the second node N2 is a gate node, the first node N1 is a source node, and the third node N3 is a drain node, will be described by way of example. However, the embodiments of the present disclosure are not limited thereto.

A gate electrode of the driving transistor D-TFT may be connected to the second node N2, and a first electrode of the driving transistor D-TFT may be connected to the first node N1. A second electrode of the driving transistor D-TFT may be connected to the third node N3. The driving transistor D-TFT may be controlled according to the voltage of the second node N2 to control the current flowing through the organic light-emitting diode OLED.

The first transistor T1 may be connected between the second node N2 and the third node N3. The first transistor T1 may be controlled in response to a first scan signal Scan1(n) to switch between the second node N2 and the third node N3.

The second transistor T2 may be connected to the first node N1. The second transistor T2 may be controlled in response to a second scan signal Scan2(n) to supply the data voltage Vdata to the first node N1.

The third transistor T3 may be connected to the first node N1. The third transistor T3 may be controlled in response to an emission control signal EM(n) to supply the high-potential driving voltage ELVDD, supplied through a high-potential driving voltage line, to the first node N1.

The fourth transistor T4 may be connected between the third node N3 and the fourth node N4. The fourth transistor T4 may be controlled in response to the emission control signal EM(n) to switch between the third node N3 and the fourth node N4.

The fifth transistor T5 may be connected to the second node N2. The fifth transistor T5 may be controlled in response to a fourth scan signal Scan4(n) to supply the initialization voltage Vini to the second node N2.

The sixth transistor T6 may be connected to the fourth node N4. The sixth transistor T6 may be controlled in response to a third scan signal Scan3(n) to supply the anode reset voltage VAR to the fourth node N4.

The seventh transistor T7 may be connected to the first node N1. The seventh transistor T7 may be controlled in response to the third scan signal Scan3(n) to supply the bias voltage Vobs to the first node N1. The hysteresis of the driving transistor D-TFT may be improved by adjusting a gate-source voltage Vgs flowing through the driving transistor D-TFT through the bias voltage Vobs. For example, the threshold voltage Vth of the driving transistor D-TFT may be changed through application of the bias voltage Vobs.

The storage capacitor Cstg may be connected between a high-potential driving voltage terminal that supplies the high-potential driving voltage ELVDD and the second node N2. The storage capacitor Cstg may store the data voltage Vdata. For example, the storage capacitor Cstg may store the data voltage Vdata during one frame.

The organic light-emitting diode OLED may include an anode and a cathode. The anode of the organic light-emitting diode OLED may be connected to the fourth node N4. The cathode of the organic light-emitting diode OLED may be connected to a low-potential driving voltage line that supplies the low-potential driving voltage ELVSS.

The organic light-emitting diode OLED may include one of an organic emission layer, an inorganic emission layer, and a quantum dot emission layer, or may include a stacked or combined structure of an organic emission layer (or inorganic emission layer) and a quantum dot emission layer. For example, the organic light-emitting diode may include an anode, an organic layer, and a cathode. In another example, in addition to the organic light-emitting diode, a micro light-emitting diode (micro-LED), a mini-LED, or a quantum dot light-emitting diode (QLED) including a quantum dot (QD) may be further used.

The organic light-emitting diode OLED may output light corresponding to one of various colors such as red, green, and blue, or may output white light.

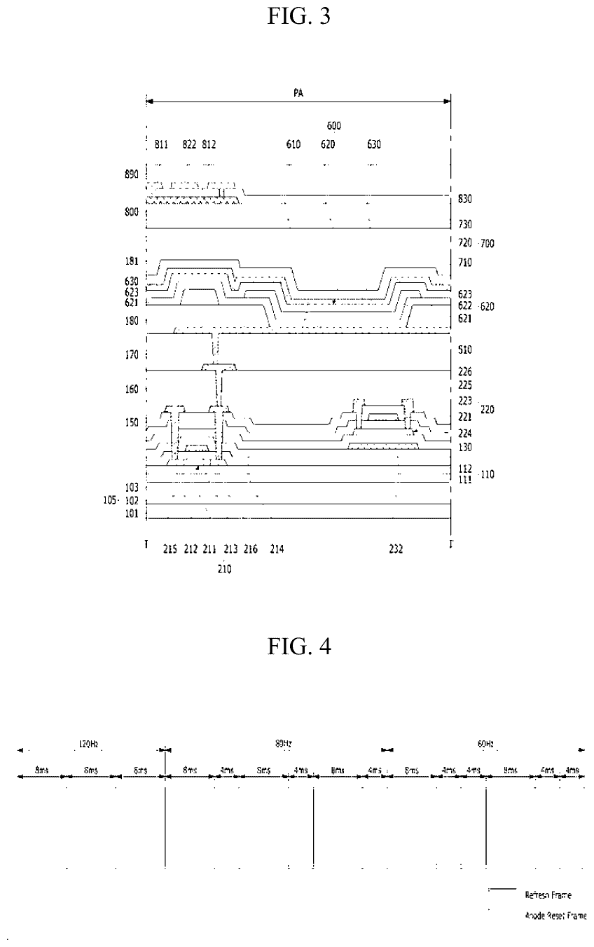

FIG. 3 is a cross-sectional view showing the display device according to an aspect of the present disclosure.

The display device according to the aspect of the present disclosure may include a device substrate 105. The device substrate 105 may include an insulative material. For example, the device substrate 105 may include glass or plastic. However, the embodiments of the present disclosure are not limited thereto. The device substrate 105 may have a multilayered structure. However, the embodiments of the present disclosure are not limited thereto. For example, the device substrate 105 may have a structure in which a first substrate layer 101, a substrate insulating layer 102, and a second substrate layer 103 are stacked. The second substrate layer 103 may include the same material as the first substrate layer 101. However, the embodiments of the present disclosure are not limited thereto. For example, the first substrate layer 101 and the second substrate layer 103 may include a polymer material such as polyimide (PI). However, the embodiments of the present disclosure are not limited thereto. The substrate insulating layer 102 may include an insulative material. Accordingly, in the display device according to the aspect of the present disclosure, the device substrate 105 may have flexibility. Therefore, in the display device according to the aspect of the present disclosure, it may be possible to prevent damage to the device substrate 105 due to bending stress.

The device substrate 105 may include an active area, a bending area, and a pad area. An image to be provided to a user may be implemented in the active area AA. For example, the active area may include a plurality of pixel areas PA. Each pixel area PA may implement a specific color. For example, a light-emitting diode 600 may be disposed in each pixel area PA. The light-emitting diode 600 may emit light of a specific color. For example, the light-emitting diode 600 may include a first electrode 610, an emission layer 620, and a second electrode 630, which are stacked on the device substrate 105.

The first electrode 610 may include a conductive material. The first electrode 610 may be made of a material having high reflectivity. For example, the first electrode 610 may include metal such as aluminum (Al) or silver (Ag). However, the embodiments of the present disclosure are not limited thereto. The first electrode 610 may have a multilayered structure. For example, the first electrode 610 may have a structure in which a reflective electrode made of metal is interposed between transparent electrodes made of a transparent conductive material such as ITO or IZO. However, the embodiments of the present disclosure are not limited thereto.

The emission layer 620 may generate light having a brightness corresponding to a voltage difference between the first electrode 610 and the second electrode 630. For example, the emission layer 620 may include an emission material layer (EML) 622 including an emission material. The emission material may include an organic material, an inorganic material, or a hybrid material. For example, the display device according to the aspect of the present disclosure may be an organic light-emitting display device in which the emission layer 620 includes an emission material layer 622 made of an organic material. However, the embodiments of the present disclosure are not limited thereto. The emission layer 620 may include an inorganic emission material. For example, the emission layer 620 may be made of a material including a quantum dot, a micro-LED, or a mini-LED. However, the embodiments of the present disclosure are not limited thereto.

The emission layer 620 may have a multilayered structure. For example, the emission layer 620 may include at least one of a first common layer 621 located between the first electrode 610 and the emission material layer 622 or a second common layer 623 located between the emission material layer 622 and the second electrode 630. Each of the first common layer 621 and the second common layer 623 may include at least one of a hole injection layer (HIL), a hole transport layer (HTL), a hole blocking layer (HBL), an electron blocking layer (EBL), an electron transport layer (ETL), or an electron injection layer (EIL). However, the embodiments of the present disclosure are not limited thereto. For example, in the display device according to the aspect of the present disclosure, the first common layer 621 may include at least one of a hole injection layer (HIL), an electron blocking layer (EBL), or a hole transport layer (HTL), and the second common layer 623 may include at least one of an electron transport layer (ETL), a hole blocking layer (HBL), or an electron injection layer (EIL).

The second electrode 630 may include a conductive material. The second electrode 630 may include a different material from the first electrode 610. However, the embodiments of the present disclosure are not limited thereto. For example, the second electrode 630 may be a transparent electrode made of a transparent conductive material such as ITO or IZO. The second electrode 630 may have higher transmittance than the first electrode 610. Accordingly, in the display device according to the aspect of the present disclosure, light generated by the emission layer 620 may be emitted through the second electrode 630.

A driving circuit may be disposed in each pixel area PA. The driving circuit may generate a driving current that is provided to the light-emitting diode 600. The driving circuit may be electrically connected to signal lines GL, DL, ELVDD, and ELVSS. For example, each pixel area PA may be composed of signal lines GL, DL, ELVDD, and ELVSS. The signal lines GL, DL, ELVDD, and ELVSS may transmit various signals for implementation of images. For example, the signal lines GL, DL, ELVDD, and ELVSS may include a gate line GL applying a gate signal, a data line DL applying a data signal, and power voltage supply lines ELVDD and ELVSS supplying power voltages. However, the embodiments of the present disclosure are not limited thereto. The driving circuit may generate a driving current corresponding to the data signal in response to the gate signal. The operation of the light-emitting diode 600 may be maintained during one frame. For example, the driving circuit may include a first thin-film transistor 210 and a second thin-film transistor 220. However, the embodiments of the present disclosure are not limited thereto.

The first thin-film transistor 210 may be electrically connected to the light-emitting diode 600. The first thin-film transistor 210 may supply a driving current corresponding to the data signal to the light-emitting diode 600. For example, the first thin-film transistor 210 may be disposed between the light-emitting diode 600 and one of the power voltage supply lines ELVDD and ELVSS. The first thin-film transistor 210 may include a first semiconductor layer 211, a first gate insulating film 212, a first gate electrode 213, a second insulating film 214, a first source electrode 215, and a first drain electrode 216.

The first semiconductor layer 211 may be located close to the device substrate 105. The first semiconductor layer 211 may include a semiconductor material. For example, the first semiconductor layer 211 may include silicon. The first semiconductor layer 211 may include a polycrystalline semiconductor. For example, the first semiconductor layer 211 may include low-temperature polysilicon (LTPS). However, the embodiments of the present disclosure are not limited thereto. In another example, the first semiconductor layer 211 may include an oxide semiconductor. The first semiconductor layer 211 may include a first source region, a first drain region, and a first channel region. The first channel region may be disposed between the first source region and the first drain region. The first channel region may have lower electrical conductivity than the first source region and the first drain region. For example, the first source region and the first drain region may include a conductive impurity having a higher concentration than that of the first channel region.

The first insulating film 212 may be disposed on the first semiconductor layer 211. The first insulating film 212 may extend to the outside of the first semiconductor layer 211. For example, the side surface of the first semiconductor layer 211 may be covered by the first insulating film 212. The first insulating film 212 may include an insulative material. For example, the first insulating film 212 may include silicon oxide (SiO) and/or silicon nitride (SiN). However, the embodiments of the present disclosure are not limited thereto. The silicon oxide (SiO) may include silicon dioxide (SiO₂). The first insulating film 212 may include a material having a high dielectric constant. For example, the first insulating film 212 may include a material such as hafnium oxide (HfO). However, the embodiments of the present disclosure are not limited thereto. The first insulating film 212 may be a gate insulating film, without being limited thereto.

The first gate electrode 213 may be disposed on the first insulating film 212. The first gate electrode 213 may include a conductive material. For example, the first gate electrode 213 may include a single layer or multiple layers including aluminum (Al), chromium (Cr), copper (Cu), titanium (Ti), molybdenum (Mo), tungsten (W), or alloys thereof. However, the embodiments of the present disclosure are not limited thereto. The first gate electrode 213 may be insulated from the first semiconductor layer 211 by the first insulating film 212. The first gate electrode 213 may overlap the first channel region of the first semiconductor layer 211. For example, the first channel region of the first semiconductor layer 211 may have electrical conductivity corresponding to the voltage applied to the first gate electrode 213.

The second insulating film 214 may be disposed on the first gate electrode 213. The second insulating film 214 may extend to the outside of the first gate electrode 213. For example, the side surface of the first gate electrode 213 may be covered by the second insulating film 214. The second insulating film 214 may extend along the first insulating film 212. The second insulating film 214 may include an insulative material. For example, the second insulating film 214 may include silicon oxide (SiO). However, the embodiments of the present disclosure are not limited thereto. The second insulating film 214 may be an interlayer insulating film, without being limited thereto.

The first source electrode 215 may be disposed on the second insulating film 214. The first source electrode 215 may be insulated from the first gate electrode 213 by the second insulating film 214. The first source electrode 215 may include a different material from the first gate electrode 213. However, the embodiments of the present disclosure are not limited thereto. The first source electrode 215 may include a conductive material. For example, the first source electrode 215 may include a single layer or multiple layers including aluminum (Al), chromium (Cr), copper (Cu), titanium (Ti), molybdenum (Mo), tungsten (W), or alloys thereof. However, the embodiments of the present disclosure are not limited thereto. The first source electrode 215 may be electrically connected to the first source region of the first semiconductor layer 211.

The first drain electrode 216 may be disposed on the second insulating film 214. The first drain electrode 216 may include a conductive material. For example, the first drain electrode 216 may include a single layer or multiple layers including aluminum (Al), chromium (Cr), copper (Cu), titanium (Ti), molybdenum (Mo), tungsten (W), or alloys thereof. However, the embodiments of the present disclosure are not limited thereto. The first drain electrode 216 may be insulated from the first gate electrode 213 by the second insulating film 214. The first drain electrode 216 may include a different material from the first gate electrode 213. However, the embodiments of the present disclosure are not limited thereto. For example, the first drain electrode 216 may include the same material as the first source electrode 215. The first drain electrode 216 may be formed through the same process as the first source electrode 215. The first drain electrode 216 may be electrically connected to the first drain region of the first semiconductor layer 211. The first drain electrode 216 may be spaced apart from the first source electrode 215.

The concrete positions of the first source electrode 215 and the first drain electrode 216 will be described later.

The second thin-film transistor 220 may be electrically connected to the first thin-film transistor 210. The second thin-film transistor 220 may transmit the data signal to the first gate electrode 213 of the first thin-film transistor 210 in response to the scan signal. For example, the second thin-film transistor 220 may be disposed between the data line DL and the first gate electrode 213 of the first thin-film transistor 210. The structure of the second thin-film transistor 220 may be identical to that of the first thin-film transistor 210. However, the embodiments of the present disclosure are not limited thereto. For example, the second thin-film transistor 220 may include a second semiconductor layer 221, a fourth insulating film 224, a second gate electrode 223, a second source electrode 225, and a second drain electrode 226.

The second semiconductor layer 221 may include a semiconductor material. The second semiconductor layer 221 may include the same material as or a different material from the first semiconductor layer 211. For example, the second semiconductor layer 221 may be an oxide semiconductor such as IGZO. In another example, the second semiconductor layer 221 may include low-temperature polysilicon (LTPS).

The second semiconductor layer 221 may be disposed on a different layer from the first semiconductor layer 211. For example, a first protective film 130 may be located on the second insulating film 214, and the second semiconductor layer 221 may be disposed on the first protective film 130. The first protective film 130 may include silicon oxide (SiOx) or silicon nitride (SiNx). However, the embodiments of the present disclosure are not limited thereto. Accordingly, in the display device according to the aspect of the present disclosure, it may be possible to prevent damage to the second semiconductor layer 221 due to the process of forming the first semiconductor layer 211.

The second semiconductor layer 221 may include a second source region, a second drain region, and a second channel region. The second channel region may be disposed between the second source region and the second drain region. The second source region and the second drain region may have lower resistance than the second channel region. For example, the second source region and the second drain region may include conductorized regions (e.g., regions with material having enhanced conductive properties) of the oxide semiconductor. The second channel region may be a non-conductorized region of the oxide semiconductor.

The fourth insulating film 224 may be disposed on the second semiconductor layer 221. The fourth insulating film 224 may include an insulative material. The fourth insulating film 224 may include the same material as the first insulating film 212. However, the embodiments of the present disclosure are not limited thereto. For example, the fourth insulating film 224 may have a multilayered structure. However, the embodiments of the present disclosure are not limited thereto.

The second gate electrode 223 may be disposed on the fourth insulating film 224. For example, the second gate electrode 223 may overlap the second channel region of the second semiconductor layer 221. The second gate electrode 223 may include a conductive material. For example, the second gate electrode 223 may include a single layer or multiple layers including aluminum (Al), chromium (Cr), copper (Cu), titanium (Ti), molybdenum (Mo), tungsten (W), or alloys thereof. However, the embodiments of the present disclosure are not limited thereto. The second gate electrode 223 may include the same material as the first gate electrode 213. However, the embodiments of the present disclosure are not limited thereto. The second gate electrode 223 may be insulated from the second semiconductor layer 221 by the fourth insulating film 224. For example, the second channel region of the second semiconductor layer 221 may have electrical conductivity corresponding to the voltage applied to the second gate electrode 223.

A second protective film 150 may be disposed on the fourth insulating film 224. The second protective film 150 may include silicon oxide (SiOx) or silicon nitride (SiNx). However, the embodiments of the present disclosure are not limited thereto.

The second source electrode 225 may be disposed on the second protective film 150. The second source electrode 225 may include a conductive material. For example, the second source electrode 225 may include aluminum (Al), chromium (Cr), copper (Cu), titanium (Ti), molybdenum (Mo), tungsten (W), or alloys thereof. However, the embodiments of the present disclosure are not limited thereto. The second source electrode 225 may include the same material as the first source electrode 215. However, the embodiments of the present disclosure are not limited thereto. The second source electrode 225 may be insulated from the second gate electrode 223 by the fourth insulating film 224. The second source electrode 225 may include a different material from the second gate electrode 223. The second source electrode 225 may be electrically connected to the second source region of the second semiconductor layer 221. For example, the fourth insulating film 224 and the second protective film 150 may include second source contact holes to partially expose the second source region of the second semiconductor layer 221. The second source electrode 225 may include a region overlapping the second source region of the second semiconductor layer 221. For example, the second source electrode 225 may be in contact with the second source region of the second semiconductor layer 221 within the second source contact holes.

The second drain electrode 226 may be disposed on the second protective film 150. The second drain electrode 226 may include a conductive material. For example, the second drain electrode 226 may include a single layer or double layers including aluminum (Al), chromium (Cr), copper (Cu), titanium (Ti), molybdenum (Mo), tungsten (W), or alloys thereof. However, the embodiments of the present disclosure are not limited thereto. The second drain electrode 226 may include the same material as the first drain electrode 216. However, the embodiments of the present disclosure are not limited thereto. The second drain electrode 226 may be insulated from the second gate electrode 223 by the fourth insulating film 224. The second drain electrode 226 may include a different material from the second gate electrode 223. However, the embodiments of the present disclosure are not limited thereto. For example, the second drain electrode 226 may include the same material as the second source electrode 225. However, the embodiments of the present disclosure are not limited thereto. The second drain electrode 226 may be formed through the same process as the second source electrode 225. The second drain electrode 226 may be electrically connected to the second drain region of the second semiconductor layer 221. The second drain electrode 226 may be spaced apart from the second source electrode 225. For example, the fourth insulating film 224 and the second protective film 150 may include second drain contact holes to partially expose the second drain region of the second semiconductor layer 221. The second drain electrode 226 may include a region overlapping the second drain region of the second semiconductor layer 221. For example, the second drain electrode 226 may be in contact with the second drain region of the second semiconductor layer 221 within the second drain contact holes.

The second thin-film transistor 220 may further include an auxiliary layer 232 located below the second semiconductor layer 221. The auxiliary layer 232 may overlap the second semiconductor layer 221. For example, the auxiliary layer 232 may include a single layer or multiple layers including aluminum (Al), chromium (Cr), copper (Cu), titanium (Ti), molybdenum (Mo), nickel (Ni), neodymium (Nd), tungsten (W), or alloys thereof. However, the embodiments of the present disclosure are not limited thereto. The auxiliary layer 232 may prevent light from reaching the second semiconductor layer 221, thereby increasing the lifespan of the second thin-film transistor 220. For example, the auxiliary layer 232 may be a light blocking layer, without being limited thereto. For example, the auxiliary layer may be formed below the first thin-film transistor 210. The auxiliary layer may be disposed on the buffer layer 112. When an auxiliary layer is formed, an insulating film may be further formed on the buffer layer 112. The auxiliary layer may be made of the same material as the auxiliary layer 232. However, the embodiments of the present disclosure are not limited thereto. The auxiliary layer may prevent light from reaching the first semiconductor layer 211, thereby increasing the lifespan of the first thin-film transistor 210.

A buffer film 110 may be disposed between the device substrate 105 and the driving circuit in each pixel area PA. The buffer film 110 may prevent contamination caused by the device substrate 105 during the process of forming the driving circuits. For example, the buffer film 110 may cover the active area AA of the device substrate 105. For example, the buffer film 110 may completely cover the active area AA of the device substrate 105. The buffer film 110 may be disposed between the device substrate 105 and the first semiconductor layer 211 in each pixel area PA. The buffer film 110 may include an insulative material. For example, the buffer film 110 may include an inorganic insulative material such as silicon oxide (SiO) or silicon nitride (SiN). However, the embodiments of the present disclosure are not limited thereto. The buffer film 110 may have a multilayered structure. For example, the buffer film 110 may have a structure in which a first buffer layer 111 and a second buffer layer 112 including a different material from the first buffer layer 111 are stacked. However, the embodiments of the present disclosure are not limited thereto.

The first protective film 130 may prevent damage to the first thin-film transistor 210 due to external impact and moisture. The first protective film 130 may extend between the auxiliary layer 230 and the second semiconductor layer 221 in each pixel area PA. Accordingly, in the display device according to the aspect of the present disclosure, it may be possible to effectively prevent damage to the first thin-film transistor 210 due to external impact and moisture.

The second protective film 150 may be disposed between the fourth insulating film 224 and the second source electrode 225 and between the fourth insulating film 224 and the second drain electrode 226 in each pixel area PA. The second protective film 150 may prevent damage to the second semiconductor layer 221 due to external impact and moisture. For example, the second protective film 150 may extend to the outside of the second semiconductor layer 221 along the fourth insulating film 224. The second protective film 150 may include a different material from the fourth insulating film 224. For example, the fourth protective film 150 may include silicon nitride (SiN). However, the embodiments of the present disclosure are not limited thereto. Accordingly, in the display device according to the aspect of the present disclosure, it may be possible to effectively prevent damage to the second semiconductor layer 221 due to external impact and moisture.

The first source electrode 215 of the first thin-film transistor may be disposed on the second protective film 150 in each pixel area PA. The first source electrode 215 may include a conductive material. For example, the first source electrode 215 may include a single layer or multiple layers including aluminum (Al), chromium (Cr), copper (Cu), titanium (Ti), molybdenum (Mo), tungsten (W), or alloys thereof. However, the embodiments of the present disclosure are not limited thereto. The first source electrode 215 may include a different material from the first gate electrode 213. However, the embodiments of the present disclosure are not limited thereto. The first source electrode 215 may be electrically connected to the first source region of the first semiconductor layer 211. For example, the first insulating film 212, the second insulating film 214, the first protective film 130, the fourth insulating film 224, and the second protective film 150 may include first contact holes to partially expose the first source region of the first semiconductor layer 211 of the first thin-film transistor 210. The first source electrode 215 may include a region overlapping the first source region of the first semiconductor layer 211. For example, the first source electrode 215 may be in contact with the first source region of the first semiconductor layer 211 within the first source contact holes.

The first drain electrode 216 of the first thin-film transistor may be disposed on the second protective film 150 in each pixel area PA. The first drain electrode 216 may include a conductive material. For example, the first drain electrode 216 may include a single layer or multiple layers including aluminum (Al), chromium (Cr), copper (Cu), titanium (Ti), molybdenum (Mo), tungsten (W), or alloys thereof. However, the embodiments of the present disclosure are not limited thereto. The first drain electrode 216 may include a different material from the first gate electrode 213. However, the embodiments of the present disclosure are not limited thereto. For example, the first drain electrode 216 may include the same material as the first source electrode 215. However, the embodiments of the present disclosure are not limited thereto. The first drain electrode 216 may be formed through the same process as the first source electrode 215. The first drain electrode 216 may be electrically connected to the first drain region of the first semiconductor layer 211. The first drain electrode 216 may be spaced apart from the first source electrode 215. For example, the first insulating film 212, the second insulating film 214, the first protective film 130, the fourth insulating film 224, and the second protective film 150 may include first contact holes to partially expose the first drain region of the first semiconductor layer 211. The first drain electrode 216 may include a region overlapping the first drain region of the first semiconductor layer 211. For example, the first drain electrode 216 may be in contact with the first drain region of the first semiconductor layer 211 within the first contact holes.

The light-emitting diode 600 in each pixel area PA may be disposed on the transistors in the corresponding pixel area PA. For example, the first thin-film transistor 210 and the second thin-film transistor 220 in each pixel area PA may be disposed between the device substrate 105 and the first electrode 610 in the corresponding pixel area PA. Accordingly, in the display device according to the aspect of the present disclosure, the area occupied by each pixel area PA may be minimized. Thus, the display device according to the aspect of the present disclosure may exhibit improved resolution.

A first protective layer 160 and a second protective layer 170 may be disposed between the driving circuit and the light-emitting diode 600 in each pixel area PA. For example, the first electrode 610, the emission layer 620, and the second electrode 630 in each pixel area PA may be disposed on the second protective layer 170 in the corresponding pixel area PA. The first protective layer 160 and the second protective layer 170 may reduce or eliminate steps caused by the transistors. For example, the upper surface of the second protective layer 170 facing the light-emitting diode 600 in each pixel area PA may be a flat surface. The first protective layer 160 and the second protective layer 170 may include an insulative material. For example, the first protective layer 160 and the second protective layer 170 may include an organic insulative material. The second protective layer 170 may include a different material from the first protective layer 160. Accordingly, in the display device according to the aspect of the present disclosure, it may be possible to effectively reduce or eliminate steps caused by the transistors.

An intermediate electrode 510 may be disposed between the first protective layer 160 and the second protective layer 170 in each pixel area PA. The light-emitting diode 600 may be electrically connected to the first drain electrode 216 of the first thin-film transistor 210 via the intermediate electrode 510. For example, the intermediate electrode 510 may penetrate the first protective layer 160 to be connected to the first drain electrode 216, and the first electrode 610 of the light-emitting diode 600 may penetrate the second protective layer 170 to be connected to the intermediate electrode 510. The intermediate electrode 510 may include a region overlapping the first drain electrode 216 and a region overlapping the first electrode 610. For example, the intermediate electrode 510 may be disposed between the first drain electrode 216 and the first electrode 610. The intermediate electrode 510 may be in contact with the first drain electrode 216. For example, the intermediate electrode 510 may be in direct contact with the first drain electrode 216. The first electrode 610 may be in contact with the intermediate electrode 510. For example, the first electrode 610 may be in direct contact with the intermediate electrode 510. The intermediate electrode 510 may include a conductive material. For example, the intermediate electrode 510 may include metal such as aluminum (Al), chromium (Cr), copper (Cu), titanium (Ti), molybdenum (Mo), or tungsten (W). The intermediate electrode 510 may include a different material from the first drain electrode 216 and the first electrode 610. However, the embodiments of the present disclosure are not limited thereto.

A bank 180 may be disposed on the second protective layer 170 in each pixel area PA. The bank 180 may include an insulative material. For example, the bank 180 may be made of a material including black pigment or an organic material such as benzocyclobutene resin, polyimide resin, acrylic resin, or photosensitive polymer. However, the embodiments of the present disclosure are not limited thereto. If the bank 180 is made of a material including black pigment or black dye, the bank 180 may be a black bank. If the bank 180 is made of a material including black pigment or black dye, light from the outside may be blocked, and the brightness of the display device may be further improved. The bank 180 may include a different material from the first protective layer 160 and the second protective layer 170. The bank 180 may cover the edge of the first electrode 610. The emission layer 620 and the second electrode 630 in each pixel area PA may be disposed on a portion of the first electrode 610 exposed by the bank 180. For example, the bank 180 may define an emission area within each pixel area PA.

A spacer 181 may be disposed on the bank 180 in each pixel area PA. The spacer 181 may be formed to have a smaller width than the bank 180. The spacer 181 may include an insulative material. For example, the spacer 181 may include an organic insulative material. The spacer 181 may be formed of the same material as the bank 180. However, the embodiments of the present disclosure are not limited thereto. The spacer 181 may prevent damage to the bank 180 and the emission material layer 622 formed in an adjacent pixel area PA due to a fine metal mask.

The emission layer 620 in each pixel area PA may extend onto the bank 180 and the spacer 181. Each pixel area PA may display a different color from that of a pixel area PA adjacent thereto. For example, the emission material layer 622 in each pixel area PA may be separated from the emission material layer 622 in a pixel area PA adjacent thereto. The emission material layer 622 in each pixel area PA may include an end portion located within the corresponding pixel area PA. The emission material layer 622 may be formed using a fine metal mask (FMM). An end portion of each emission material layer 622 may be disposed on the bank 180 and the spacer 181. The first common layer 621 and the second common layer 622 of each emission layer 620 may extend along the surface of the bank 180. For example, the first common layer 621 and the second common layer 623 in each pixel area PA may be connected to the first common layer 621 and the second common layer 623 in a pixel area PA adjacent thereto. Accordingly, in the display device according to the aspect of the present disclosure, process efficiency may be improved.

The voltage supplied to the second electrode 630 in each pixel area PA may be identical to the voltage supplied to the second electrode 630 in a pixel area PA adjacent thereto. For example, the second electrode 630 in each pixel area PA may be connected to the second electrode 630 in a pixel area PA adjacent to the bank 180. Accordingly, the display device according to the aspect of the present disclosure may control brightness of each pixel area PA through the gate signal and the data signal applied to the corresponding pixel area PA. The second electrode 630 in each pixel area PA may be in contact with the second electrode 630 in a pixel area PA adjacent thereto.

An encapsulation member 700 may be disposed on the light-emitting diode 600 in each pixel area PA. The encapsulation member 700 may prevent damage to the light-emitting diodes 600 due to external impact and moisture. The encapsulation member 700 may have a multilayered structure. However, the embodiments of the present disclosure are not limited thereto. For example, the encapsulation member 700 may include a first encapsulation layer 710, a second encapsulation layer 720, and a third encapsulation layer 730. However, the embodiments of the present disclosure are not limited thereto. The first encapsulation layer 710, the second encapsulation layer 720, and the third encapsulation layer 730 may include an insulative material. The second encapsulation layer 720 may include a different material from the first encapsulation layer 710 and the third encapsulation layer 730. However, the embodiments of the present disclosure are not limited thereto. For example, the first encapsulation layer 710 and the third encapsulation layer 730 may include an inorganic insulative material, and the second encapsulation layer 720 may include an organic insulative material. Accordingly, in the display device according to the aspect of the present disclosure, it may be possible to effectively prevent damage to the light-emitting diodes 600 due to external impact and moisture. Steps caused by the light-emitting diode 600 in each pixel area PA may be removed by the encapsulation member 700. For example, the upper surface of the encapsulation member 700 facing the device substrate 105 may be a flat surface.

The touch unit may be disposed on the encapsulation member 700. The touch unit may detect touch of a user and/or a tool. For example, the touch unit may include touch electrodes 811 and 822 and bridge electrodes 812. The touch electrodes 811 and 822 may be disposed parallel to each other. The bridge electrodes 812 may interconnect the touch electrodes 811 and 822. The touch electrodes 811 and 822 and the bridge electrodes 812 may include a conductive material. For example, the touch electrodes 811 and 822 and the bridge electrodes 812 may include a single layer or double layers including aluminum (Al), chromium (Cr), copper (Cu), titanium (Ti), molybdenum (Mo), tungsten (W), or alloys thereof. However, the embodiments of the present disclosure are not limited thereto. The touch electrodes 811 and 822 and the bridge electrodes 812 may overlap the active area of the device substrate 105. The light-emitting diode 600 in each pixel area PA may be disposed outside the touch electrodes 811 and 822 and the bridge electrodes 812. For example, the touch electrodes 811 and 822 and the bridge electrodes 812 may overlap the bank 180. The touch electrodes 811 and 822 and the bridge electrodes 812 may be spaced apart from the light-emitting diode 600 in each pixel area PA. Accordingly, in the display device according to the aspect of the present disclosure, light emitted from each light-emitting diode 600 in a direction perpendicular to the upper surface of the device substrate 105 may not be blocked by the touch electrodes 811 and 822 and the bridge electrodes 812. Therefore, in the display device according to the aspect of the present disclosure, it may be possible to prevent reduction in brightness of each pixel area PA due to the touch electrodes 811 and 822 and the bridge electrodes 812.

A touch insulating film 830 may be disposed between the bridge electrodes 812 and the touch electrodes 811 and 822. The touch insulating film 830 may include an insulative material. For example, the touch insulating film 830 may include a material such as silicon oxide (SiOx) or silicon nitride (SiNx). However, the embodiments of the present disclosure are not limited thereto. The second touch electrodes 822 may be disposed on the same layer as the first touch electrodes 811. For example, the touch electrodes 811 and 822 and bridge electrodes interconnecting the touch electrodes 822 may be disposed on the touch insulating film 830 covering the bridge electrodes 812. The touch insulating film 830 may include touch contact holes to partially expose the bridge electrode 812. The touch electrode 811 may be connected to the corresponding bridge electrode 812 through one of the touch contact holes.

A touch buffer film 800 may be disposed between the encapsulation member 700 and the elements 811, 812, and 822 of the touch unit. The touch buffer film 800 may prevent damage to the encapsulation member 700 and the light-emitting diodes 600 due to the process of forming the touch electrodes 811 and 822 and the bridge electrodes 812. The touch buffer film 800 may include an insulative material. For example, the touch buffer film 800 may include a material such as silicon oxide (SiOx) or silicon nitride (SiNx). However, the embodiments of the present disclosure are not limited thereto.

An insulating film 890 may be disposed on the elements 811, 812, and 822 of the touch unit. The insulating film 890 may prevent damage to the elements 811, 812, and 822 of the touch unit due to external impact and moisture.

FIG. 4 is a diagram for explaining an operation method of the display device according to an aspect of the present disclosure.

The display device according to the present disclosure described with reference to FIGS. 1 and 2 may employ variable refresh rate (VRR) technology to implement low power consumption. The display device may be driven using the VRR technology that varies a frequency.

For example, the display device may be driven at 120 Hz and may then be driven at 60 Hz. If the display device is driven while varying the frequency, it is necessary to reduce visibility when varying the frequency. Therefore, when the display device is driven at 120 Hz and then is driven at 60 Hz, intermediate frequencies (80 Hz, 48 Hz, etc.) may be used to reduce visibility.

To use intermediate frequencies, the display device needs to be driven using an anode reset frame. For example, the anode reset frame may be set to 4 ms (Scan3 240 Hz). However, the embodiments of the present disclosure are not limited thereto.

To implement driving using the anode reset frame, an anode reset line ARL for supplying an anode reset signal VAR to each pixel P may be required.

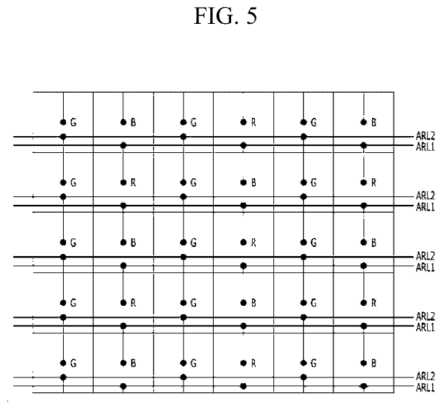

FIG. 5 is a layout diagram showing anode reset lines of the display device according to an aspect of the present disclosure.

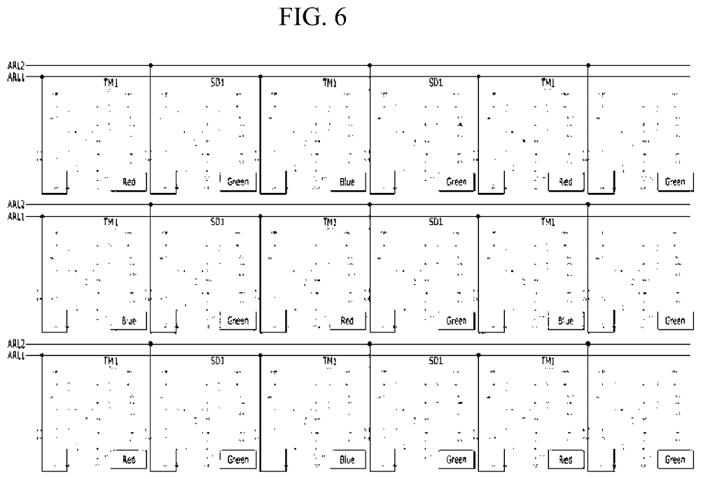

FIG. 6 is a layout diagram showing the circuit configuration and anode reset lines of each pixel in the display device according to an aspect of the present disclosure.

In the display device according to the aspect of the present disclosure, different anode reset lines ARL may be connected to a plurality of pixels P to improve voltage deviation of the fourth node N4 and to improve current leakage and color variation when the organic light-emitting diode OLED emits light.

For example, a first pixel and a second pixel may be connected to a first anode reset line ARL1, and a third pixel may be connected to a second anode reset line ARL2.

The first and second anode reset lines ARL1 and ARL2 may be disposed in each pixel row such that the first anode reset line ARL1 is connected to the first pixel and the second pixel and the second anode reset line ARL2 is connected to the third pixel.

As shown in FIGS. 5 and 6, the first and second anode reset lines ARL1 and ARL2 may be disposed in each pixel row. The first pixel and the second pixel disposed in the corresponding pixel row may be connected to the first anode reset line ARL1. The third pixel disposed in the corresponding pixel row may be connected to the second anode reset line ARL2. However, the embodiments of the present disclosure are not limited thereto. Each of the first pixel and the second pixel may be one of a red pixel R and a blue pixel B, without being limited thereto. The third pixel may be a green pixel G, without being limited thereto.

For example, the red pixel R disposed in the corresponding pixel row and the blue pixel B disposed in the corresponding pixel row may be connected to the first anode reset line ARL1, and the green pixel G disposed in the corresponding pixel row and the green pixel G disposed in the corresponding pixel row may be connected to the second anode reset line ARL2.

In another example, the red pixel R disposed in the corresponding pixel row and the green pixel G disposed in the corresponding pixel row may be connected to the first anode reset line ARL1, and the blue pixel B disposed in the corresponding pixel row and the blue pixel B disposed in the corresponding pixel row may be connected to the second anode reset line ARL2.

In still another example, the blue pixel B disposed in the corresponding pixel row and the green pixel G disposed in the corresponding pixel row may be connected to the first anode reset line ARL1, and the red pixel R disposed in the corresponding pixel row and the red pixel R disposed in the corresponding pixel row may be connected to the second anode reset line ARL2.

Although it is illustrated in FIG. 5 that the first pixel and the second pixel disposed in the corresponding pixel row are connected to the first anode reset line ARL1 and the third pixel disposed in the corresponding pixel row is connected to the second anode reset line ARL2, the embodiments of the present disclosure are not limited thereto. In another example, the first pixel and the second pixel disposed in the next pixel row may be connected to the first anode reset line ARL1, and the third pixel disposed in the next pixel row may be connected to the second anode reset line ARL2.

As shown in FIG. 6, the first pixel and the second pixel disposed in the corresponding pixel row may be connected to the first anode reset line ARL1, and the third pixel disposed in the corresponding pixel row may be connected to the second anode reset line ARL2.

According to the aspect of the present disclosure, two anode reset lines may be disposed in each pixel. For example, two anode reset lines may individually apply an anode reset voltage to the green pixel G, the red pixel R, and the blue pixel B. As a result, the freedom of voltage setting may be improved, and thus the performance of the display panel may be improved.

As shown in FIG. 6, a high-potential driving voltage line for supplying a high-potential driving voltage ELVDD to the organic light-emitting diode OLED may be disposed in each pixel. To supply uniform high-potential driving voltages ELVDD to all of the pixels of the display device, the high-potential driving voltage lines may be formed in a mesh structure.

For example, the high-potential driving voltage lines of the pixels may be electrically connected to each other via a connection line TM1, which is made of the same material as the gate electrode of at least one of the thin-film transistors constituting the circuit of each pixel, and a connection line SD1, which is made of the same material as the source/drain electrodes of at least one of the thin-film transistors.

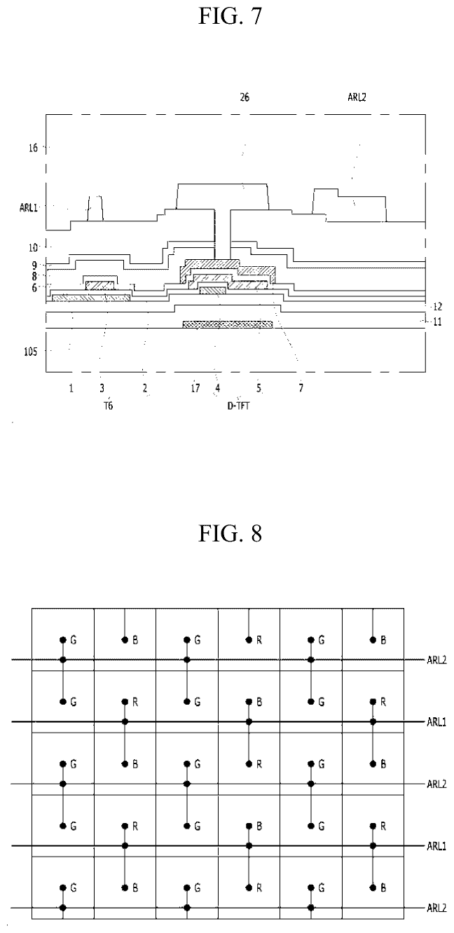

FIG. 7 is an exemplary cross-sectional view showing the connection relationship of the anode reset lines according to an aspect of the present disclosure.

FIG. 7 exemplarily shows a driving transistor D-TFT and a sixth transistor T6 that supplies the anode reset voltage VAR to the fourth node N4 in the circuit diagram of the pixel described with reference to FIG. 2.

For example, a light blocking layer 17 may be disposed on the device substrate 105 at a position below the driving transistor D-TFT. A plurality of buffer layers 11 and 12 may be disposed on the light blocking layer 17. The plurality of buffer layers 11 and 12 may include an inorganic insulative material. However, the embodiments of the present disclosure are not limited thereto. The plurality of buffer layers 11 and 12 may prevent permeation of moisture through an interface of the device substrate 105. The buffer layers 11 and 12 may correspond to the buffer layers 111 and 112 shown in FIG. 3.

A sixth transistor T6, which includes a first semiconductor layer 1, a first insulating film 2, and a first gate electrode 3, may be formed on the plurality of buffer layers 11 and 12.

A driving transistor D-TFT, which includes a second semiconductor layer 4, a first insulating film 2, and a second gate electrode 5, may be formed on the plurality of buffer layers 11 and 12 at a position above the light blocking layer 17.

A second insulating film 6 may be disposed on the entire surface of the device substrate 105 on which the first gate electrode 3 and the second gate electrode 5 are formed. A metal layer 7 (corresponding to TM1 shown in FIG. 6) may be disposed on the second insulating film 6 at a position above the second gate electrode 5, and thus a storage capacitor Cstg may be formed between the second gate electrode 5 of the driving transistor D-TFT and the metal layer 7. The metal layer 7 may be a gate electrode, without being limited thereto. For example, the metal layer 7 may be disposed on the second gate electrode 5, and may be a third gate electrode.

A first protective film 8, a second protective film 9, and a third protective film 10 may be formed on the entire surface of the device substrate 105 on which the metal layer 7 is formed.

A connection line 26 (corresponding to SD1 shown in FIG. 6), a first anode reset line ARL1, and a second anode reset line ARL2 may be disposed on the third protective film 10. The connection line 26 may be electrically connected to the metal layer 7 (TM1) on the driving transistor D-TFT. For example, contact holes may be formed in the first protective film 8, the second protective film 9, and the third protective film 10, and the connection line 26 may be disposed to be electrically connected to the metal layer 7 (TM1) on the driving transistor D-TFT through the contact holes. In addition, a fourth protective film 16 may be disposed on the connection line 26, the first anode reset line ARL1, and the second anode reset line ARL2.

FIG. 8 is a layout diagram showing anode reset lines of the display device according to an aspect of the present disclosure.

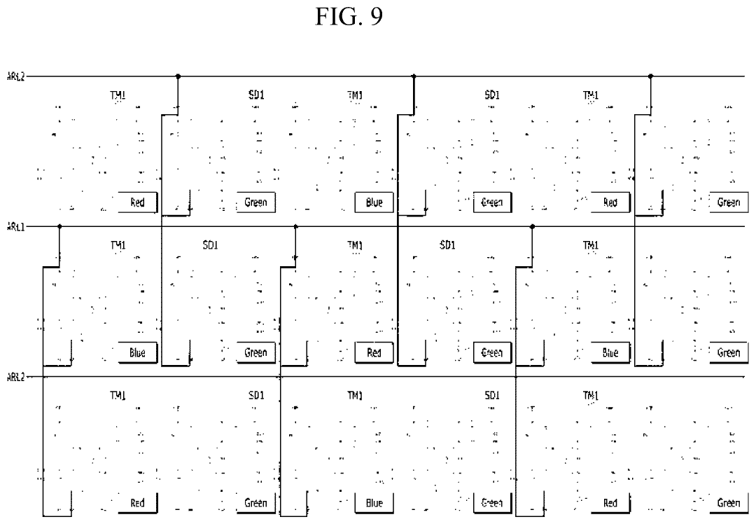

FIG. 9 is a layout diagram showing the circuit configuration and anode reset lines of each pixel in the display device according to an aspect of the present disclosure.

As shown in FIGS. 8 and 9, a green pixel G, a blue pixel B, a green pixel G, a red pixel R, a green pixel G, and a blue pixel B may be disposed in that order in a (2k−1)^{th} pixel row (k being a natural number). For example, one pixel may include a red pixel R, a green pixel G, a blue pixel B, and a green pixel G. However, the embodiments of the present disclosure are not limited thereto.

A green pixel G, a red pixel R, a green pixel G, a blue pixel B, a green pixel G, and a red pixel R may be disposed in that order in a 2k^{th} pixel row. However, the embodiments of the present disclosure are not limited thereto.

For convenience of description, although the pixels of the respective colors of an aspect of the present disclosure are described with reference to FIGS. 8 and 9, the embodiments of the present disclosure are not limited thereto. In another aspect, a blue pixel B, a green pixel G, a blue pixel B, a red pixel R, a blue pixel B, and a green pixel G may be disposed in that order in the (2k−1)^{th} pixel row, and a blue pixel B, a red pixel R, a blue pixel B, a green pixel G, a blue pixel B, and a red pixel R may be disposed in that order in the 2k^{th} pixel row.

In another aspect, a red pixel R, a green pixel G, a red pixel R, a blue pixel B, a red pixel R, and a green pixel G may be disposed in that order in the (2k−1)^{th} pixel row, and a red pixel R, a blue pixel B, a red pixel R, a green pixel G, a red pixel R, and a blue pixel B may be disposed in that order in the 2k^{th} pixel row.

In two adjacent pixel rows, two pixels of the same color may be disposed, and the remaining two pixels of different colors may be disposed in an alternating manner in the vertical direction.

The second anode reset line ARL2 may be disposed in the (2k−1)^{th} pixel row, and the first anode reset line ARL1 may be disposed in the 2k^{th} pixel row.

A first pixel and a second pixel disposed in two adjacent pixel rows may be connected to the first anode reset line ARL1, and two third pixels disposed in two adjacent pixel rows may be connected to the second anode reset line ARL2.

According to the aspect of the present disclosure, a red pixel R and a blue pixel B disposed in the vertical direction in two adjacent pixel rows may be connected to the first anode reset line ARL1. Two green pixels G disposed in the vertical direction in two adjacent pixel rows may be connected to the second anode reset line ARL2. However, the embodiments of the present disclosure are not limited thereto.

For example, a red pixel R and a green pixel G disposed in the vertical direction in two adjacent pixel rows may be connected to the first anode reset line ARL1, and two blue pixels B disposed in the vertical direction in two adjacent pixel rows may be connected to the second anode reset line ARL2.

In another example, a blue pixel B and a green pixel G disposed in the vertical direction in two adjacent pixel rows may be connected to the first anode reset line ARL1, and two red pixels R disposed in the vertical direction in two adjacent pixel rows may be connected to the second anode reset line ARL2.

In the display device according to the other aspect of the present disclosure, the number of first and second anode reset lines ARL1 and ARL2 may be reduced to half, and thus overlap capacitance formed due to overlap between the anode reset lines and the signal lines of the GIP may be reduced. In addition, occurrence of a ripple in the anode reset voltage VAR, supplied through the anode reset line, due to a coupling effect of the overlap capacitance may be reduced.

Therefore, due to reduction in ripple of the anode reset voltage VAR, it may be possible to prevent occurrence of band-shaped mura in the center portion of the display panel. For example, it may be possible to prevent occurrence of center-band mura (CBM) defects at the center of the display panel.

According to the other aspect of the present disclosure, the first anode reset line ARL1 and the second anode reset line ARL2 may be disposed in each pixel row, two adjacent first anode reset lines ARL1 may be connected to each other, and two adjacent second anode reset lines ARL2 may be connected to each other, whereby each of the first and second anode reset lines ARL1 and ARL2 may be disposed in a mesh structure. Accordingly, overlap capacitance may be reduced, and a ripple of the anode reset voltage VAR may be reduced, with a result that it may be possible to prevent occurrence of band-shaped mura in the center portion of the display panel. In addition, since each of the first and second anode reset lines ARL1 and ARL2 is configured as lines for formation of a mesh structure, capacitance between the lines may be reduced, and there is no need to place separate lines, thus simplifying a process.

As shown in FIG. 9, a high-potential driving voltage line for supplying a high-potential driving voltage ELVDD to the organic light-emitting diode OLED may be disposed in each pixel. To supply uniform high-potential driving voltages ELVDD to all of the pixels of the display device, the high-potential driving voltage lines may be formed in a mesh structure.

For example, the high-potential driving voltage lines of the pixels may be electrically connected to each other via a connection line TM1, which is made of the same material as the gate electrode of at least one of the thin-film transistors constituting the circuit of each pixel, and a connection line SD1, which is made of the same material as the source/drain electrodes of at least one of the thin-film transistors.

In this configuration, the connection line SD1 may be cut such that the high-potential driving voltage ELVDD is supplied to one side of the connection line SD1 and the other side of the connection line SD1 is used as the anode reset line ARL1 or ARL2 that supplies the anode reset voltage VAR.

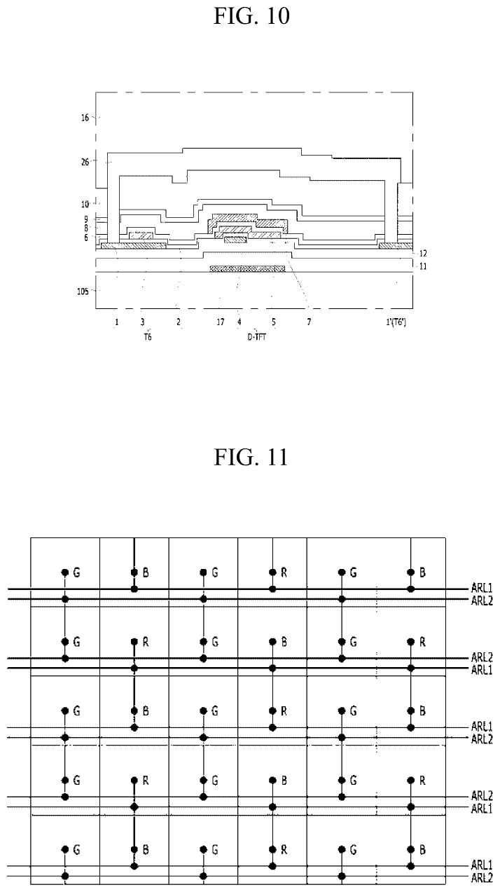

FIG. 10 is an exemplary cross-sectional view showing the connection relationship of the anode reset lines according to an aspect of the present disclosure.

FIG. 10 exemplarily shows a driving transistor D-TFT and a sixth transistor T6 that supplies the anode reset voltage VAR to the fourth node N4 in the circuit diagram of the pixel described with reference to FIG. 2. The circuit diagram of each pixel shown in FIG. 10 may be substantially identical to that shown in FIG. 2.

For example, a light blocking layer 17 may be disposed on the device substrate 105 at a position below the driving transistor D-TFT. A plurality of buffer layers 11 and 12 may be disposed on the light blocking layer 17. The plurality of buffer layers 11 and 12 may include an inorganic insulative material. However, the embodiments of the present disclosure are not limited thereto. The plurality of buffer layers 11 and 12 may prevent permeation of moisture through an interface of the device substrate 105. The buffer layers 11 and 12 may correspond to the buffer layers 111 and 112 shown in FIG. 3.

A sixth transistor T6, which includes a first semiconductor layer 1, a first insulating film 2, and a first gate electrode 3, may be formed on the plurality of buffer layers 11 and 12.

A driving transistor D-TFT, which includes a second semiconductor layer 4, a gate insulating film 2, and a second gate electrode 5, may be formed on the plurality of buffer layers 11 and 12 at a position above the light blocking layer 17.

A second insulating film 6 may be disposed on the entire surface of the device substrate 105 on which the first gate electrode 3 and the second gate electrode 5 are formed. A metal layer 7 may be disposed on the second insulating film 6 at a position above the second gate electrode 5, and thus a storage capacitor Cstg may be formed between the second gate electrode 5 of the driving transistor D-TFT and the metal layer 7. For example, the metal layer 7 may be a gate electrode. However, the embodiments of the present disclosure are not limited thereto. For example, the metal layer 7 may be disposed on the second gate electrode 5, and may be a third gate electrode.

A first protective film 8, a second protective film 9, and a third protective film 10 may be disposed on the entire surface of the device substrate 105 on which the metal layer 7 is formed.

A connection line 26 may be disposed on the third protective film 10. The connection line 26 may electrically connect the first semiconductor layer 1 of the sixth transistor T6 of the corresponding pixel to a first semiconductor layer 1′ of a sixth transistor T6′ of an adjacent pixel. For example, contact holes may be formed in the first protective film 8, the second protective film 9, and the third protective film 10 so that a portion of the first semiconductor layer 1 of the sixth transistor T6 of the corresponding pixel and a portion of the first semiconductor layer 1′ of the sixth transistor T6′ of the adjacent pixel are exposed. The connection line 26 may be disposed on the third protective film 10 to electrically connect the first semiconductor layer 1 of the sixth transistor T6 of the corresponding pixel to the first semiconductor layer 1′ of the sixth transistor T6′ of the adjacent pixel through the contact holes. The connection line 26 may connect the corresponding pixel to a neighboring pixel in the vertical direction. For example, when the corresponding pixel is a blue pixel, the vertically neighboring pixel is a red pixel. Thus, the blue pixel and the red pixel may be connected to the connection line 26 in the vertical direction.

In addition, the fourth protective film 16 may be disposed on the connection line 26.

According to the present disclosure, the metal layer 7 and the connection line 26 may not be connected to each other, one side of the metal layer 7 may be connected to a line to which the high-potential driving voltage ELVDD is applied, and the other side of the metal layer 7 may be connected to the connection line 26. For example, the metal layer 7 may be cut such that the high-potential driving voltage ELVDD is supplied to one side of the metal layer 7 and the other side of the metal layer 7 is configured as the connection line 26 that supplies the anode reset voltage VAR. For example, the other side of the metal layer 7 may be connected to the connection line 26 in the vertical direction.

FIG. 11 is a layout diagram showing anode reset lines of the display device according to an aspect of the present disclosure.

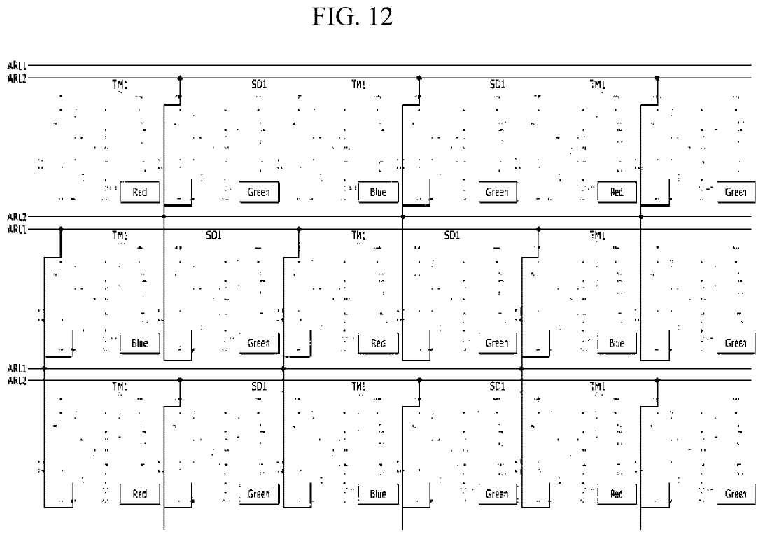

FIG. 12 is a layout diagram showing the circuit configuration and anode reset lines of each pixel in the display device according to an aspect of the present disclosure.

As shown in FIGS. 11 and 12, a green pixel G, a blue pixel B, a green pixel G, a red pixel R, a green pixel G, and a blue pixel B may be disposed in that order in a (2k−1)^{th} pixel row. However, the embodiments of the present disclosure are not limited thereto.

A green pixel G, a red pixel R, a green pixel G, a blue pixel B, a green pixel G, and a red pixel R may be disposed in that order in a 2k^{th} pixel row. However, the embodiments of the present disclosure are not limited thereto.

For convenience of description, although the pixels of the respective colors of an aspect are described with reference to FIGS. 11 and 12, the embodiments of the present disclosure are not limited thereto. As described above with reference to FIGS. 8 and 9, in two adjacent pixel rows, two pixels of the same color may be disposed, and the remaining two pixels of different colors may be disposed in the vertical direction. Such arrangement may be repeated in an alternating manner.

The first anode reset line ARL1 and the second anode reset line ARL2 may be disposed in each pixel row.

The first anode reset line ARL1 and the second anode reset line ARL2 may be disposed in that order in the (2k−1)^{th} pixel row, and the second anode reset line ARL2 and the first anode reset line ARL1 may be disposed in that order in the 2k^{th} pixel row.

In addition, a first pixel and a second pixel disposed in the corresponding pixel row may be connected to the first anode reset line ARL1. A third pixel disposed in the corresponding pixel row may be connected to the second anode reset line ARL2.

According to another aspect of the present disclosure, when the anode reset lines are disposed, two adjacent first anode reset lines ARL1 may be connected to each other, so that the two adjacent first anode reset lines ARL1 may have a mesh structure.

In addition, two adjacent second anode reset lines ARL2 may be connected to each other, so that the two adjacent second anode reset lines ARL2 may also have a mesh structure.

Therefore, when the first and second anode reset lines ARL1 and ARL2 are disposed in each pixel row, two adjacent first anode reset lines ARL1 are connected to each other to have a mesh structure, and two adjacent second anode reset lines ARL2 are connected to each other to have a mesh structure. Accordingly, a ripple of the anode reset voltage VAR may be reduced. As a result, it may be possible to prevent occurrence of band-shaped mura in the center portion of the display panel.

According to the present disclosure, the connection relationship of the anode reset lines may be substantially identical to that described with reference to FIG. 10.

The display device according to various embodiments of the present disclosure may be applied to mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wallpaper display apparatuses, signage apparatuses, game machines, notebook computers, monitors, cameras, camcorders, home appliances, etc.

A display device according to various embodiments of the present disclosure may be described as follows.

A display device according to various embodiments of the present disclosure may include a substrate on which a plurality of pixels is disposed in a column direction and a row direction, a light-emitting diode disposed in each of the plurality of pixels, a first anode reset line disposed in each row in which some pixels among the plurality of pixels are located, and a second anode reset line disposed in the each row in which the remaining pixels among the plurality of pixels are located.

According to various embodiments of the present disclosure, the plurality of pixels may include a first pixel connected to the first anode reset line, a second pixel connected to the first anode reset line, and a third pixel connected to the second anode reset line.

According to various embodiments of the present disclosure, the first pixel disposed in a corresponding pixel row and the second pixel disposed in the next pixel row may be connected to the first anode reset line. The third pixel disposed in the corresponding pixel row and the third pixel disposed in the next pixel row may be connected to the second anode reset line.

According to various embodiments of the present disclosure, the first anode reset line and the second anode reset line may be disposed in each pixel row.

According to various embodiments of the present disclosure, two adjacent first anode reset lines may be connected to each other to have a mesh structure. Two adjacent second anode reset lines may be connected to each other to have a mesh structure.

According to various embodiments of the present disclosure, the first pixel and the second pixel disposed in the corresponding pixel row may be connected to the first anode reset line. The third pixel disposed in the corresponding pixel row may be connected to the second anode reset line.

According to various embodiments of the present disclosure, each of the plurality of pixels may include one or more transistors, a driving transistor, and a storage capacitor.

According to various embodiments of the present disclosure, a semiconductor layer of each of the driving transistor and the transistors may be an oxide semiconductor layer or a low-temperature polysilicon semiconductor layer.

According to various embodiments of the present disclosure, the driving transistor may be connected to a second node. The transistors may include a first transistor connected between the second node and a third node, a second transistor connected to a first node, a third transistor connected to the first node, a fourth transistor connected between the third node and a fourth node, a fifth transistor connected to the second node, a sixth transistor connected to the fourth node, and a seventh transistor connected to the first node.

According to various embodiments of the present disclosure, the display device may further include a storage capacitor connected between a high-potential driving voltage terminal and the second node.

According to various embodiments of the present disclosure, the light-emitting diode may be connected between the fourth node and a low-potential driving voltage terminal.

According to various embodiments of the present disclosure, the first anode reset line may be disposed in a 2k^{th} pixel row (k being a natural number). The second anode reset line may be disposed in a (2k−1)^{th} pixel row.

According to various embodiments of the present disclosure, the third pixel, the second pixel, the third pixel, the first pixel, the third pixel, and the second pixel may be disposed in that order in the (2k−1)^{th} pixel row. The third pixel, the first pixel, the third pixel, the second pixel, the third pixel, and the first pixel may be disposed in that order in the 2k^{th} pixel row.

According to various embodiments of the present disclosure, the second pixel and the first pixel disposed in a vertical direction in two adjacent pixel rows may be connected to the first anode reset line. The third pixel and another third pixel disposed in the vertical direction in two adjacent pixel rows may be connected to the second anode reset line.

According to various embodiments of the present disclosure, each of the plurality of pixels may include one or more transistors and a driving transistor. The first anode reset line or the second anode reset line may include the same material as source and drain electrodes of one of the transistors and the driving transistor.

A display device according to various embodiments of the present disclosure may include a substrate on which a plurality of pixels is disposed in a column direction and a row direction, light-emitting diodes disposed in the plurality of pixels, and a first anode reset line and a second anode reset line disposed in each pixel row. The first anode reset line and the second anode reset line may be disposed in a (2k−1)^{th} pixel row (k being a natural number). The second anode reset line and the first anode reset line may be disposed in a 2k^{th} pixel row. Two adjacent first anode reset lines may be connected to each other to have a mesh structure, and two adjacent second anode reset lines may be connected to each other to have a mesh structure.

A display device according to various embodiments of the present disclosure may include a substrate on which a plurality of pixels is disposed in a column direction and a row direction, light-emitting diodes disposed in the plurality of pixels, a second anode reset line disposed in a (2k−1)^{th} pixel row (k being a natural number), and a first anode reset line disposed in a 2k^{th} pixel row. A third pixel disposed in the (2k−1)^{th} pixel row and a third pixel disposed in the 2k^{th} pixel row may be connected to the second anode reset line. A first pixel disposed in the 2k^{th} pixel row and a second pixel disposed in a (2k+1)^{th} pixel row may be connected to the first anode reset line.

A display device according to various embodiments of the present disclosure may include a substrate on which a plurality of pixels is disposed in a column direction and a row direction, light-emitting diodes disposed in the plurality of pixels, a first anode reset line disposed in each of odd-numbered pixel rows and connecting pixels of different colors among the light-emitting diodes, and a second anode reset line disposed in each of even-numbered pixel rows and connecting pixels of the same color among the light-emitting diodes.

According to various embodiments of the present disclosure, each of the plurality of pixels may include one or more transistors, a driving transistor, and a storage capacitor.

According to various embodiments of the present disclosure, a semiconductor layer of each of the driving transistor and the transistors may be an oxide semiconductor layer or a low-temperature polysilicon semiconductor layer.

According to various embodiments of the present disclosure, the display device may further include an encapsulation member disposed on the light-emitting diodes and a touch unit disposed on the encapsulation member.

As is apparent from the above description, according to the present disclosure, voltage deviation of an anode and color variation may be improved by applying different anode reset voltages to a plurality of pixels.

According to the present disclosure, in a display device that is driven in a VRR manner, an anode reset line for supplying an anode reset voltage to an anode of a light-emitting diode may be minimized or may be disposed in a mesh structure. Therefore, it may be possible to reduce overlap capacitance formed due to overlap between anode reset lines and signal lines of a GIP.

According to the present disclosure, occurrence of a ripple in the anode reset voltage VAR, supplied through the anode reset line, due to a coupling effect of overlap capacitance may be prevented.

According to the present disclosure, due to reduction in ripple of the anode reset voltage VAR, it may be possible to prevent occurrence of band-shaped mura in the center portion of a display panel.

According to the present disclosure, since overlap capacitance formed due to overlap between anode reset lines and signal lines of a GIP is reduced and occurrence of a ripple in the anode reset voltage VAR supplied through the anode reset line is prevented, the defect rate of the display device may be reduced. Therefore, the amount of energy consumed to produce the display device may be reduced, and the amount of greenhouse gases generated during a manufacturing process may be reduced. As a result, the present disclosure has environment/social/governance (ESG) effects.

Those skilled in the art will understand that various modification and alternations are possible from the above description without departing from the technical idea of the present disclosure. Consequently, the technical scope of the present disclosure is defined by the appended claims, not by the detailed description of the present disclosure.

What is claimed is:

1. A display device comprising:
a substrate on which a plurality of pixels is disposed in a column direction and a row direction;
a first anode reset line disposed in each row in which a first subset of pixels among the plurality of pixels are located; and
a second anode reset line disposed in each row in which a second subset of pixels among the plurality of pixels are located.

2. The display device according to claim 1, wherein the plurality of pixels comprises:
a first pixel connected to the first anode reset line;
a second pixel connected to the first anode reset line; and
a third pixel connected to the second anode reset line.

3. The display device according to claim 2, wherein the first pixel disposed in a corresponding pixel row and the second pixel disposed in a next pixel row are connected to the first anode reset line, and
wherein the third pixel disposed in the corresponding pixel row and the third pixel disposed in the next pixel row are connected to the second anode reset line.

4. The display device according to claim 2, wherein the first anode reset line and the second anode reset line are disposed in each pixel row.

5. The display device according to claim 4, wherein the first anode reset line and another first anode reset line adjacent thereto are connected to each other to have a mesh structure, and
wherein the second anode reset line and another second anode reset line adjacent thereto are connected to each other to have a mesh structure.

6. The display device according to claim 4, wherein the first pixel and the second pixel disposed in a corresponding pixel row are connected to the first anode reset line, and
wherein the third pixel disposed in the corresponding pixel row is connected to the second anode reset line.

7. The display device according to claim 1, wherein each of the plurality of pixels comprises one or more transistors, a driving transistor, and a storage capacitor.

8. The display device according to claim 7, wherein a semiconductor layer of each of the driving transistor and the one or more transistors is an oxide semiconductor layer or a low-temperature polysilicon semiconductor layer.

9. The display device according to claim 8, wherein the driving transistor is connected to a second node, and
wherein the one or more transistors comprise:
a first transistor connected between the second node and a third node;
a second transistor connected to a first node;
a third transistor connected to the first node;
a fourth transistor connected between the third node and a fourth node;
a fifth transistor connected to the second node;
a sixth transistor connected to the fourth node; and
a seventh transistor connected to the first node.

10. The display device according to claim 9, further comprising a storage capacitor connected between a high-potential driving voltage terminal and the second node.

11. The display device according to claim 9, wherein a light-emitting diode is connected between the fourth node and a low-potential driving voltage terminal.

12. The display device according to claim 1, wherein the first anode reset line is disposed in a 2k^{th} pixel row (k being a natural number), and
wherein the second anode reset line is disposed in a (2k−1)^{th} pixel row.

13. The display device according to claim 12, wherein a first pixel, a second pixel, the first pixel, a third pixel, the first pixel, and the second pixel are disposed in that order in the (2k−1)^{th} pixel row, and
wherein the first pixel, the third pixel, the first pixel, the second pixel, the first pixel, and the third pixel are disposed in that order in the 2k^{th} pixel row.

14. The display device according to claim 13, wherein the third pixel and the second pixel disposed in a vertical direction in two adjacent pixel rows are connected to the first anode reset line, and
wherein the first pixel and another first pixel disposed in the vertical direction in two adjacent pixel rows are connected to the second anode reset line.

15. The display device according to claim 1, wherein each of the plurality of pixels comprises one or more transistors and a driving transistor, and
wherein the first anode reset line or the second anode reset line include the same material as source and drain electrodes of one of the one or more transistors and the driving transistor.

16. A display device comprising:
a substrate;
a plurality of pixels on the substrate;
a first anode reset line;
a second anode reset line,
wherein each of the plurality of pixels is connected to one of the first anode reset line or the second anode reset line,
wherein the first anode reset line and another first anode reset line adjacent thereto are connected to each other to form a mesh structure, and
wherein the second anode reset line and another second anode reset line adjacent thereto are connected to each other to form the mesh structure.

17. The display device according to claim 16, wherein a first pixel, a second pixel, the first pixel, a third pixel, the first pixel, and the second pixel are disposed in that order in a (2k−1)^{th} pixel row (k being a natural number), and
wherein the first pixel, the third pixel, the first pixel, the second pixel, the first pixel, and the third pixel are disposed in that order in a 2k^{th} pixel row.

18. A display device comprising:
a substrate on which a plurality of pixels is disposed in a column direction and a row direction;
a first anode reset line disposed in a 2k^{th} pixel row (k being a natural number); and
a second anode reset line disposed in a (2k−1)^{th} pixel row;
wherein a first pixel disposed in the (2k−1)^{th} pixel row and another first pixel disposed in the 2k^{th} pixel row are connected to the second anode reset line, and
wherein a second pixel disposed in the 2k^{th} pixel row and another second pixel disposed in a (2k+1)^{th} pixel row are connected to the first anode reset line.

19. The display device according to claim 18, wherein the first pixel, the second pixel, the first pixel, a third pixel, the first pixel, and the second pixel are disposed in that order in the (2k−1)^{th} pixel row, and
wherein the first pixel, the third pixel, the first pixel, the second pixel, the first pixel, and the third pixel are disposed in that order in the 2k^{th} pixel row.

20. A display device comprising:
a substrate on which a plurality of pixels is disposed in a column direction and a row direction;
light-emitting diodes disposed in the plurality of pixels;
a first anode reset line disposed in each of odd-numbered pixel rows and connecting pixels of different colors among the light-emitting diodes; and
a second anode reset line disposed in each of even-numbered pixel rows and connecting pixels of the same color among the light-emitting diodes.

21. The display device according to claim 20, wherein each of the plurality of pixels comprises one or more transistors, a driving transistor, and a storage capacitor, and
wherein a semiconductor layer of each of the driving transistor and the one or more transistors is an oxide semiconductor layer or a low-temperature polysilicon semiconductor layer.

22. The display device according to claim 20, further comprising:
an encapsulation member disposed on the light-emitting diodes; and
a touch unit disposed on the encapsulation member.
